(19) United States
(12) Patent Application Publication
(10) Pub. No.: US 2016/0146083 A1
(43) Pub. Date: May 26, 2016

(54) CLAMP MOUNTED THERMOELECTRIC GENERATOR

(71) Applicants: Hyundai Motor Company, Seoul (KR); Kia Motors Corporation, Seoul (KR); Hyundai America Technical Center, Inc., Superior Township, MI (US)

(72) Inventors: Sui Lang, Ann Arbor, MI (US); Nayan Engineer, Canton, MI (US); Paul Neuman, Saline, MI (US)

(21) Appl. No.: 14/553,130

(22) Filed: Nov. 25, 2014

(51) Int. Cl. F01N 5/02; H01L 35/30

(52) U.S. Cl. CPC F01N 5/025; H01L 35/30

(57) ABSTRACT

In one embodiment, a system is disclosed that includes a clamp that defines a substantially cylindrical aperture. One or more thermoelectric generator (TEG) layers are coupled to the clamp and receive heat from the clamp. The TEG layers may be formed using thermoelectric nanostructures. One or more heat sinks are also coupled to the one or more TEG layers that provide cooling to the TEG layers.

### BACKGROUND

(a) Technical Field

The present disclosure generally relates to thermoelectric generators (TEGs). In particular, a clamp mounted TEG is disclosed for attachment to an engine exhaust system.

(b) Background Art

Thermoelectric generators (TEGs) are devices that are capable of converting heat into electrical energy. TEGs can be employed to improve operational efficiency of a myriad of applications. One such application is automobiles, where TEGs may be utilized to recover usable energy from automobile waste heat. More specifically, a TEG may convert waste heat, e.g., exhaust heat, in an internal combustion engine (IC) into electricity. This electricity may then be utilized by other components within the automobile, which can increase the overall fuel economy and improve vehicle emissions, e.g., a charge for a battery, electrical components, etc.

Current automobile TEGs, however, suffer from drawbacks which can hinder the device's potential usefulness. For example, current automobile TEGs are typically complex in their assembly and are difficult to remove. As a result, modifying the engine design may be necessary to accommodate the TEG and repairing and/or replacing the TEG can be expensive and time-consuming. In addition, these modifications also typically prevent older vehicles from being retrofitted with a TEG. Therefore, there is currently a need for a TEG which is highly efficient, yet has a minimal size and weight, is easily removable, and has an assembly of minimal complexity.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

The present invention provides systems and methods for attaching one or more TEGs to an engine exhaust system. In particular, a modular, clamp mounted TEG is disclosed that allows one or more TEGs to be attached to existing engine exhaust systems.

In one embodiment, a system is disclosed that includes a clamp that defines a substantially cylindrical aperture. One or more thermoelectric generator (TEG) layers are coupled to the clamp and receive heat from the clamp. The TEG layers may be formed using thermoelectric nanostructures. One or more heat sinks are also coupled to the one or more TEG layers that provide cooling to the TEG layers.

In one aspect, the system may include one or more thermal insulation layers located between the clamp and the one or more heat sinks. In another aspect, the one or more heat sinks are cooling fins and may be constructed using aluminum. In a further aspect, the clamp may include a crescent shaped upper portion and a crescent shaped lower portion, with the upper and lower portions of the clamp being coupled by opposing hinges. In another aspect, the system also includes an exhaust pipe of an engine located within the aperture of the clamp. In some aspects, the heat received by the one or more TEG layers is provided by heated exhaust gas within the exhaust pipe. In a further aspect, the system also includes a plurality of electrically connected TEG clamps, each TEG clamp comprising a clamp, one or more TEG layers, and one or more heat sinks. The TEG clamps may be coupled to an exhaust pipe of an engine and, in one aspect, may be coupled to the exhaust pipe between a catalytic converter and a muffler.

In another embodiment, a method is disclosed in which one or more thermoelectric generator (TEG) layers are coupled to an exhaust pipe of an engine. The TEG layers may be formed using thermoelectric nanostructures. Heat is transferred to the one or more TEG layers and cooling is also provided to the one or more TEG layers. Electricity is generated by the one or more TEG layers by converting the transferred heat into electrical energy.

In one aspect, opposing sides of a particular TEG layer may be thermally isolated. In another aspect, cooling fins may be used to provide the cooling to the one or more TEG layers. In some aspect, the one or more TEG layers may be coupled to the exhaust pipe at a location between a catalytic converter and a muffler. In one aspect, TEG layers coupled to the exhaust pipe using different clamps may be electrically connected. In a further aspect, the heat may be transferred to one side of a particular TEG layer that opposes a second side of the particular TEG layer to which the cooling is provided. In another aspect, the one or more TEG layers may be constructed using a silicon-based nanostructure.

In a further embodiment, an apparatus is disclosed. The apparatus includes means for converting heat from an exhaust pipe into electrical energy. The apparatus also includes means for coupling the heat converting means to the exhaust pipe.

In one aspect, the apparatus may also include means for cooling the heat converting means. In another aspect, the apparatus may include means for removing the heat converting means from the exhaust pipe.

Advantageously, the techniques described herein provide for systems and methods whereby heat from exhaust gas from an engine may be converted into electrical energy.

### BRIEF DESCRIPTION OF THE DRAWINGS

The above and other features of the present invention will now be described in detail with reference to certain exemplary embodiments thereof illustrated the accompanying drawings which are given herein below by way of illustration only, and thus are not limitative of the present invention, and wherein:

FIG. 1 illustrates an example exhaust system for a vehicle having attached thermoelectric generators (TEGs);

FIG. 2 illustrates an example TEG system for an exhaust pipe;

FIG. 3 illustrates an example exploded view of the TEG system of FIG. 2; and

FIG. 4 illustrates an example graph of electrical power generation by a TEG.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, the present disclosure will be described so as to be easily embodied by those skilled in the art.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, plug-in hybrid electric vehicles, and other alternative fuel vehicles (e.g., fuels derived from resources other than petroleum). As referred to herein, a hybrid vehicle is a vehicle that has two or more sources of power, for example both gasoline-powered and electric-powered vehicles.

Additionally, it is understood that some of the methods may be executed by at least one controller. The term controller refers to a hardware device that includes a memory and a processor configured to execute one or more steps that should be interpreted as its algorithmic structure. The memory is configured to store algorithmic steps and the processor is specifically configured to execute said algorithmic steps to perform one or more processes which are described further below.

Furthermore, the control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present invention generally provides a modular thermoelectric generator (TEG) system that can be coupled to an exhaust pipe of an engine. Heat from exhaust gas within the pipe is transferred to one or more TEG elements and converted into electrical power.

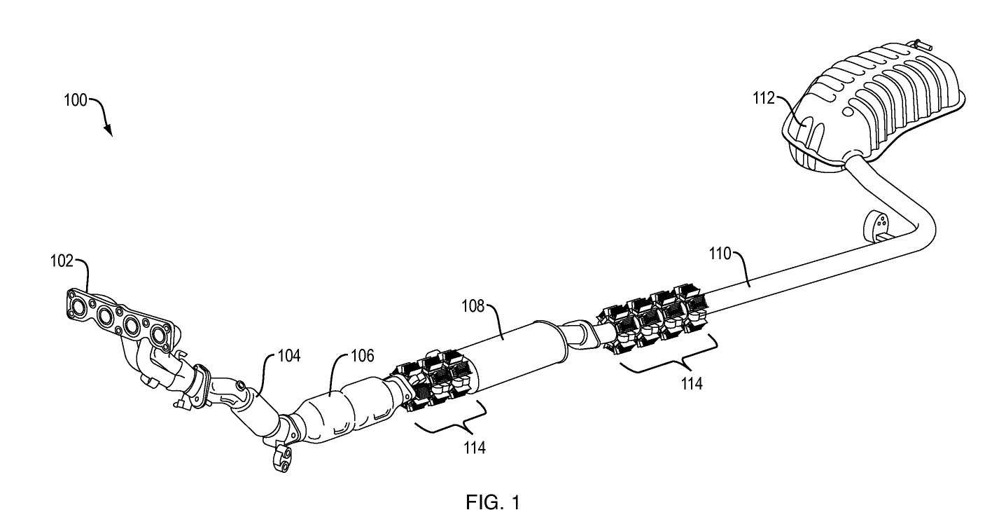

Referring now to FIG. 1, an example exhaust system for a vehicle is shown, according to various embodiments. Exhaust system 100 generally operates to remove exhaust gas from a coupled engine after combustion. As shown, for example, exhaust system 100 may include an exhaust manifold 102 that is coupled to the engine and provides a path for exhaust gas within the engine to be diverted away from the engine's combustion chambers.

In some embodiments, exhaust system 100 also includes a catalytic converter 106 coupled to exhaust manifold 102 via a front exhaust pipe 104. In general, catalytic converter 106 operates to remove pollutants from the exhaust gas prior to exhaust system 100 releasing the gas into the atmosphere. For example, catalytic converter 106 may chemically react carbon monoxide (CO) or unburnt hydrocarbons present in the exhaust gas to produce carbon dioxide (CO₂) and/or water (H₂O). In some cases, catalytic converter 106 may be a three-way system that also chemically reduces NOx gasses (e.g., nitrogen dioxide, etc.) into less harmful nitrogen (N2) and oxygen (O2) gasses.

Exhaust system 100 may also include a muffler 112 that operates to reduce noise produced by the engine and exhaust system 100. As shown, muffler 112 may be coupled to catalytic converter 106 via a rear pipe 110, resonator 108, and/or a center pipe that connects catalytic converter 106 to resonator 108 (not shown). It is to be appreciated that exhaust system 100 is only one example of an exhaust system and that other exhaust systems may utilize other configurations (e.g., by relocating, removing, or adding components) without deviating from the scope of the invention.

According to various embodiments, thermoelectric generator (TEG) systems 114 may be coupled to an exhaust pipe (e.g., rear pipe 110, a center pipe located between resonator 108 and catalytic converter 106, etc.) in exhaust system 100. Generally speaking, TEG systems 114 operate by converting heat present in the exhaust gas into electrical energy. In some cases, up to 40% of combustion energy produced by an engine may be lost as heat within the engine's exhaust gas. TEG systems 114 may be utilized to recapture some of this energy by converting the heat in the exhaust gas into electrical energy. For example, TEG systems 114 may be electrically connected to the battery of the vehicle, allowing the recovered energy to be stored until needed. In some cases, the alternator of the vehicle can also be downsized as a result of the recovered electrical energy. As shown, the modular nature of TEG systems 114 allows for any number of TEG systems 114 to be coupled to an exhaust pipe. In some cases, TEG systems 114 are each connected separately to a storage system (e.g., the vehicle's battery). In other cases, TEG systems 114 are electrically connected to one another.

While TEG systems 114 are shown herein primarily with respect to vehicle exhaust systems, it is to be appreciated that TEG systems 114 may be adapted for use with any other form of non-vehicle exhaust system.

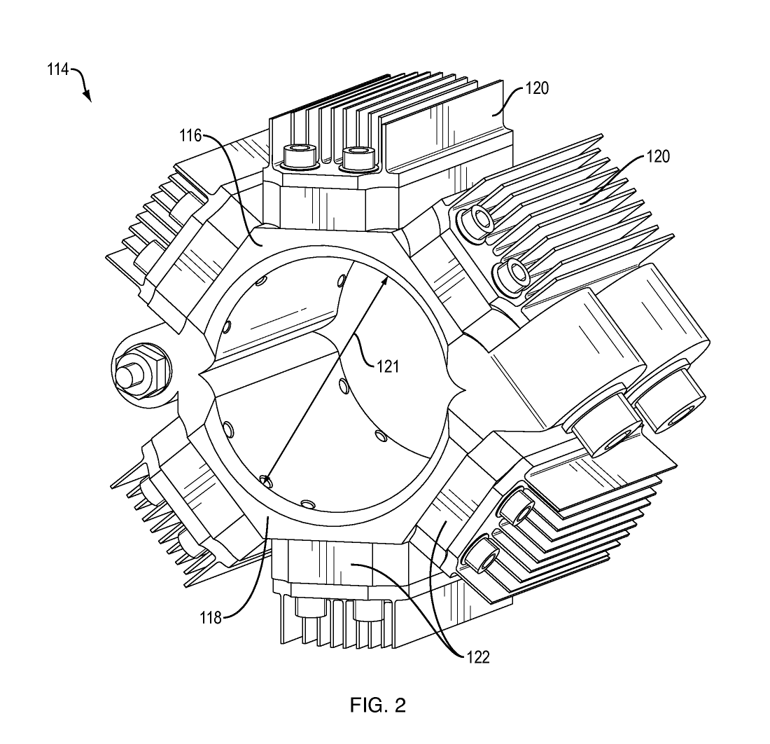

Referring now to FIG. 2, an example TEG system 114 is shown, according to various embodiments. In various embodiments, TEG system 114 is a clamp that couples TEG system 114 to an exhaust pipe. In one embodiment, TEG system 114 includes a crescent shaped upper portion 116 and a crescent shaped lower portion 118 that, when coupled, define a substantially cylindrical shaped aperture 121. The diameter of aperture 121 may be sized accordingly to accommodate an exhaust pipe. While the clamp mechanism shown in FIG. 2 comprises two portions (e.g., portions 116, 118), any number of segments may be used in other embodiments.

Extending radially outward from the clamp formed by portions 116, 118 are a number of TEG housings 122 that are coupled to the clamp. Any number of TEG housings 122 and corresponding TEGs may be used in TEG system 114. A shown, for example, each of upper and lower portions 116, 118 may be coupled to three TEG housings 122. For example, the exterior of the clamp formed by upper and lower portions 116, 118 may generally form a hexagonal shape with a TEG housing 122 coupled to each side of the hexagon. In other embodiments, upper and lower portions 116, 118 may form an n-sided polygon (e.g., a square shape, a pentagonal shape, etc.), with a corresponding number of TEG housings 122 coupled to each side. In another embodiment, upper and lower portions 116, 118 form a cylindrical exterior and one or more TEG housings 122 may be adapted and coupled to the clamp (e.g., each of TEG housings 122 may have a curved base).

In some embodiments, TEG system 100 may also include one or more heat sinks 120 coupled to TEG housings 122 that provide cooling to the TEGs housed therein. In one embodiment, heat sinks 120 are constructed using a thermally conductive material, such as aluminum. As shown, heat sinks 120 may include a number of fin structures to increase the surface area of heat sinks 120, thereby increasing the amount of cooling provided to TEG housings 122. In various embodiments, TEG housings 122 may be constructed using a thermally insulating material (e.g., ceramics, polymers, etc.), so as to thermally isolate heat sinks 120 from the heated exhaust pipe.

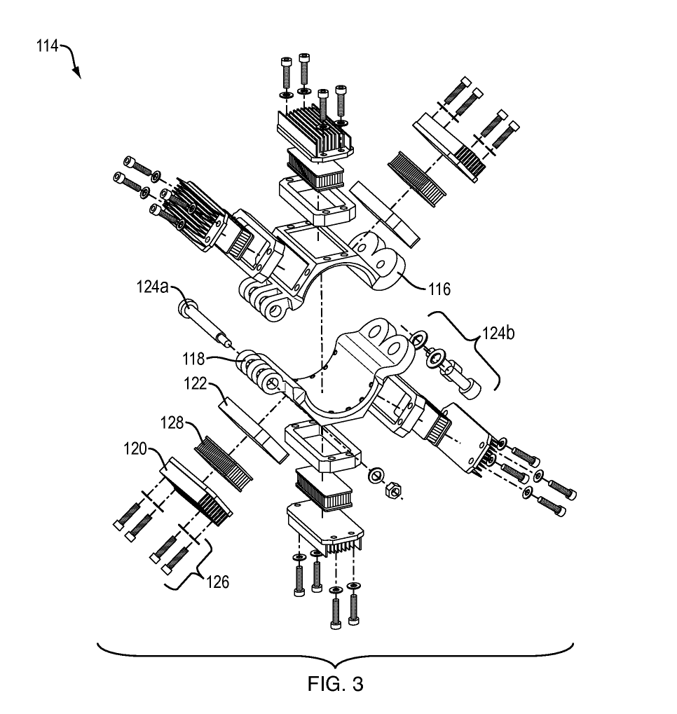

FIG. 3 illustrates an example exploded view of TEG system 114, according to various embodiments. As described previously, TEG system 114 includes upper and lower portions 116, 118 that may be affixed to one another and clamped around an exhaust pipe. In one embodiment, portions 116, 118 are coupled by fasteners 124a and 124b fitted through apertures on opposing ends of portions 116, 118. As shown, for example, fastener 124a may be inserted through apertures on opposing ends of portions 116, 118 that form a hinge. On the opposite side of portions 116, 118, fasteners 124b may be inserted through apertures located on portions 116, 118 that extend substantially perpendicular to the hinge through which fastener 124a is inserted. As will be appreciated, the coupling means shown are illustrative only and that upper and lower portions 116, 118 may be coupled using other means, such as welding, fasteners that extend perpendicular to the exhaust pipe, etc., according to other embodiments. When coupled, upper and lower portions 116, 118 provide compressive force to the exhaust pipe, to prevent movement of TEG system 114.

Located within TEG housings 122 are TEG layers 128 that convert heat into electrical energy. Each of TEG layers 128 may be constructed using a silicon-based nanostructure, or alternatively, composed of other suitable compounds comprising, for example, bismuth, lead, magnesium, selenium, tellurium, germanium, antimony, nichrome, and the like. The silicon-based nanostructure is a highly efficient TEG-adaptable material, which allows for the size of the TEG layers 128 to be significantly reduced. A single TEG pair may consist of one n-type (e.g., material having an excess of electrons) and one p-type nanostructure (e.g., material having an excess of holes), or alternatively, one n-type nanostructure or one p-type nanostructure. Nanostructure and nanophase material suitable for use in TEG layers 128 may include, but are not limited to, nanoporous material, nanowire, and nano-dimensional precipitates and lamellae formation in bulk materials. In one embodiment, one or more dimensions of the structure and/or phases is larger than the mean-free-path of the electron or hole. In another embodiment, one or more dimensions of the structure and/or phases is smaller than the phonon wavelength of the material.

To provide a temperature differential across TEG layers 128 and to dissipate heat from the exhaust gas, heat sinks 120 are coupled to TEG layers 128 and extend radially away from the exhaust pipe. During operation, heat from the exhaust gas passing through the exhaust pipe is transferred through upper and lower portions 116, 118 and into one side of a particular TEG layer 128. On the opposing side, the coupled heat sink 120 dissipates heat from TEG layer 128, providing a temperature differential within the layer. This temperature differential produces a current within TEG layer 128 and the generated electrical energy may be sent to a storage device (e.g., a battery, super-capacitor, etc.) for later use by the vehicle. In other embodiments, other cooling mechanisms may be used in addition to, or in lieu of, heat sinks 120. For example, TEG layers 128 may be coupled to water jackets and be liquid cooled, on other embodiments.

Notably, while “layer” may be used herein with respect to various components of TEG system 114, this term is intended to describe the physical locations of the components within system 114 and not their actual construction. For example, as would be appreciated, TEG layer 128 may comprise any number of TEG arrays that may or may not be “layered,” such as pairs of oppositely doped materials. Said differently, the term “layer” is not intended to be limiting to particular types or formations of materials.

In some embodiments, TEG housings 122 may thermally isolate heat sinks 120 from the clamp formed by upper and lower portions 116, 118. For example, TEG housings 122 may be constructed using materials that have low thermal conductivity (e.g., polymers, ceramics, etc.), thereby enhancing the temperature differential between the opposing sides of TEG layers 128.

In one embodiment, heat sinks 120, TEG housings 122, and TEG layers 128 may be coupled to upper and lower portions 116, 118 using fasteners 126. Fasteners 126 may, for example, be inserted through heat sinks 120 and into portions 116, 118, thereby sandwiching heat sinks 120, TEG layers 128, and TEG housings 122 together. In other embodiments, other fastening mechanism may be used.

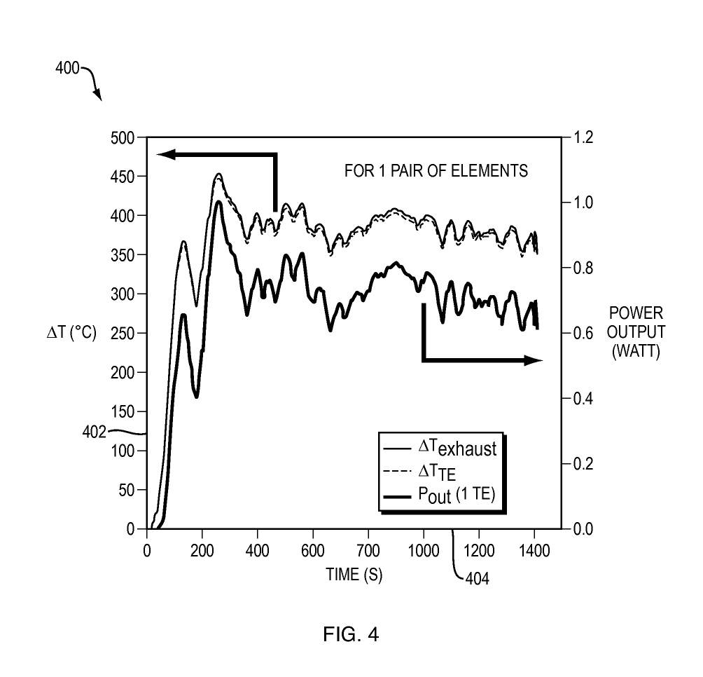

Referring now to FIG. 4, an example graph 400 of electrical power generation by a TEG is shown, according to various embodiments. As shown, the amount of electrical power generated by a pair of TEG elements is plotted a function of temperature differential 402 and time 404.

Based on a city driving cycle, the temperature of exhaust gas ranges typically ranges from 350-450° C. Temperature from airflow around an exhaust pipe has also been shown to range from 25-45° C., depending on the speed of the vehicle and the ambient temperature. Thus, a TEG system in accordance with to the teachings herein has the potential of producing a temperature differential of approximately 400° C. From graph 400, it can be seen that a 400 degree temperature difference in pair of TEG elements generates approximately 1 Watt (W) of power. Notably, the temperatures depicted in FIG. 4 are illustrative only and may vary depending on the configuration of the vehicle itself (e.g., the available amount of airflow for cooling may depend on the shape of the vehicle), the configuration of the vehicle's exhaust system, and/or the relative location of a TEG system within the exhaust system (e.g., temperatures may be greater upstream in the exhaust system than downstream).

As mentioned previously, up to 40% of energy losses from a combustion engine are attributable to heat within the exhaust gas. For a typical 100 horsepower engine operating at peak horsepower and generating 75 kW of power, up to 30 kW of this power may be lost via heated exhaust gas. A typical TEG module described herein has been shown to provide between 4-10% recovery of energy, meaning that between 1.2 kW and 3 kW of power may potentially be recapture as electrical power using the systems described herein.

Advantageously, the techniques described herein provide for a modular TEG system that can be attached to an exhaust pipe of an engine, such as those used in vehicles. The modular nature of the design allows for any number TEG systems to be coupled to the exhaust pipe, allowing downstream waste heat to be recaptured as electrical energy. The designs provided herein also allow TEG systems to be attached to existing exhaust systems without significant modification.

While the embodiment of the present disclosure has been described in detail, the scope of the right of the present disclosure is not limited to the above-described embodiment, and various modifications and improved forms by those skilled in the art who use the basic concept of the present disclosure defined in the appended claims also belong to the scope of the right of the present disclosure.

What is claimed is:

1. A system, comprising:
a clamp that defines a substantially cylindrical aperture;
one or more thermoelectric generator (TEG) layers coupled to the clamp and receive heat from the clamp, wherein the TEG layers comprise thermoelectric nanostructures; and
one or more heat sinks coupled to the one or more TEG layers that provide cooling to the TEG layers.

2. The system as in claim 1, wherein the one or more heat sinks comprise cooling fins.

3. The system as in claim 2, wherein the cooling fins comprise aluminum.

4. The system as in claim 1, further comprising:
one or more thermal insulation layers located between the clamp and the one or more heat sinks.

5. The system as in claim 1, wherein the clamp comprises:
a crescent shaped upper portion; and
a crescent shaped lower portion,
wherein the upper and lower portions of the clamp are coupled by opposing hinges.

6. The system as in claim 1, further comprising:
an exhaust pipe of an engine located within the aperture of the clamp.

7. The system as in claim 6, wherein the heat received by the one or more TEG layers is provided by heated exhaust gas within the exhaust pipe.

8. The system as in claim 1, further comprising:
a plurality of electrically connected TEG clamps, each TEG clamp comprising a clamp, one or more TEG layers, and one or more heat sinks.

9. The system as in claim 8, wherein the TEG clamps are coupled to an exhaust pipe of an engine.

10. The system as in claim 9, wherein the TEG clamps are coupled to the exhaust pipe between a catalytic converter and a muffler.

11. A method comprising:
coupling one or more thermoelectric generator (TEG) layers to an exhaust pipe of an engine, wherein the TEG layers comprise thermoelectric nanostructures;
transferring heat to the one or more TEG layers;
providing cooling to the one or more TEG layers; and
generating electricity by the one or more TEG layers by converting the transferred heat into electrical energy.

12. The method as in claim 11, further comprising:
thermally isolating opposing sides of a particular TEG layer via a housing that comprises a thermally insulating material.

13. The method as in claim 11, further comprising:
using cooling fins to provide the cooling to the one or more TEG layers.

14. The method as in claim 11, further comprising:
coupling the one or more TEG layers to the exhaust pipe at a location between a catalytic converter and a muffler.

15. The method as in claim 11, further comprising:
electrically connecting TEG layers that are coupled to the exhaust pipe using different clamps.

16. The method as in claim 11, further comprising:
transferring the heat to a first side of a particular TEG layer, wherein the first side of the particular TEG layer opposes a second side of the particular TEG layer to which the cooling is provided.

17. The method as in claim 11, wherein the one or more TEG layers comprise a silicon-based nanostructure.

18. An apparatus comprising:
means for converting heat from an exhaust pipe into electrical energy; and
means for coupling the heat converting means to the exhaust pipe.

19. The apparatus as in claim 18, comprising:
means for cooling the heat converting means.

20. The apparatus as in claim 18, comprising:
means for removing the heat converting means from the exhaust pipe.
